(19) United States
(12) Patent Application Publication
(10) Pub. No.: US 2023/0156911 A1
(43) Pub. Date: May 18, 2023

(54) FLEXIBLE WIRING BODY, DRIVING SYSTEM, AND IMAGING DEVICE

(71) Applicant: TOHOKU UNIVERSITY, Sendai-shi, Miyagi (JP)

(72) Inventors: Shuji TANAKA, Sendai-shi, Miyagi (JP); Takashiro TSUKAMOTO, Sendai-shi, Miyagi (JP)

(21) Appl. No.: 17/798,866

(22) PCT Filed: Feb. 9, 2021
(86) PCT No.: PCT/JP2021/004696

§ 371 Date: Nov. 10, 2022

(30) Foreign Application Priority Data
Feb. 10, 2020 (JP) 2020-021006

(51) Int. Cl. H05K 1/02; H02N 1/00; H02K 41/035; H04N 23/68; H04M 1/02; H04N 23/54

(52) U.S. Cl. CPC H05K 1/028; H05K 1/0237; H02N 1/006; H02K 41/0354; H04N 23/687; H04M 1/0264; H04N 23/54; H05K 2201/10151; H05K 2201/052; H04M 2250/52

(57) ABSTRACT

A driving system (7) includes an actuator (71A) that performs at least one among translations in three directions orthogonal to one another and rotations about axes in the three directions, and a flexible wiring body (73A) that connects a semiconductor element (6) moving along with the actuator (71A) and a frame (72) positioned outer than the semiconductor element (6). The flexible wiring body (73A) is provided with a main part (731A) mounted with the semiconductor element (6) and electrically connected to the semiconductor element (6), and a plurality of arm parts (732A) extending from the main part (731A) toward the frame (72) and bent three-dimensionally.

### TECHNICAL FIELD

The present invention relates to a flexible wiring body, a driving system, and an imaging device.

The invention claims priority based on JP-A-2020-021006 filed in Japan on Feb. 10, 2020, and the description thereof is incorporated herein.

### BACKGROUND ART

Camera of smartphones or the like include ones having a mechanical optical image stabilization (OIS) function and a mechanical focusing function. Such cameras are achieved by translating a lens with a voice coil motor (VCM).

On the other hand, there is also an OIS system that moves an image sensor (CMOS imager or the like) instead of moving a lens. The rotation of the lens about its center axis does not achieve any effect, whereas the movement of the image sensor can correct camera shake in a rotation direction, which is a feature of the sensor shift type OIS system. Such an OIS system was too large and expensive for a smartphone, and was therefore employed only in a single-lens reflex camera.

However, in recent years, there is an increasing demand for adopting a sensor shift type OIS system for a smartphone. In order to be mounted on a smartphone, the OIS system needs to be made sufficiently small and manufactured at a lower cost, and thus the use of micro electro mechanical systems (MEMS) technology has been studied.

An actuator that translates and rotates can be achieved with substantially the same footprint as an imaging element by using MEMS technology. However, when adopting a design in which a large displacement of several tens of pm or more is generated in multiple axes, a generated force of the actuator is reduced. On the other hand, several tens of wires need to be taken out from the image sensor, and some of the wires are high-frequency wires for high-speed communication, and some other wires are power supply wires for supplying a current to the image sensor, which has a large power consumption. In order to move the image sensor, such wires need to be moved (dragged) together, and resistances thereof become a large load for the small actuator. Therefore, in order to achieve a compact OIS system of the sensor shift type, one of the keys is how to take out the wires from the image sensor while increasing the generated force of the actuator.

In the related art, there is a multi-axis MEMS assembly that includes a MEMS actuator configured to perform three-axis movement. For example, there is disclosed a MEMS actuator including a conductive bent part having one end mounted to a MEMS actuator core and the other end mounted to an outer frame, in which the conductive bent part supplies an electric signal from an image sensor on the MEMS actuator core to the outer frame (PTL 1). Further, there is disclosed a MEMS actuator that has a structure in which a U-shaped thin film wire connected to an outer frame and an inner frame is raised upward by pressing the outer frame from the periphery thereof and fixing bars constituting the outer frame with a latch structure (PTL 2). In this MEMS actuator, the U-shaped thin film wire is deformed to fall or rise in accordance with the movement of the image sensor, thereby reducing a mechanical load (mechanical resistance) of a large number of wires.

### CITATION LIST

### Patent Literature

PTL 1: US Patent Application Publication No. 2019/0227266

PTL 2: US Patent Application Publication No. 2015/0341534

### SUMMARY OF INVENTION

### Technical Problem

However, the technique according to PTL 1 does not disclose whether the conductive bent part allows both a high-frequency signal for high-speed communication and a large current for driving the image sensor to flow, and thus there is room for improvement. Further, according to the technique according to PTL 2, a structure of the outer frame is complex and an assembly process of the MEMS actuator is complicated, and there is a concern of positioning performance of the image sensor mounted to the MEMS actuator.

An object of the invention is to provide a flexible wiring body, a driving system, and an imaging device that can stably flow both a high-frequency signal for high-speed communication and a large current for driving an image sensor, can improve positioning performance of the image sensor mounted to an actuator, and can cope with large-scale production without requiring a complicated assembly process.

### SOLUTION TO PROBLEM

In order to achieve the above object, the invention provides the following solutions.

[1] A flexible wiring body configured to connect a semiconductor element and a frame positioned outer than the semiconductor element, the semiconductor element being configured to move along with an actuator configured to perform at least one among translations in three directions orthogonal to one another and rotations about axes in the three directions, the flexible wiring body including:

a main part mounted with the semiconductor element and electrically connected to the semiconductor element; and a plurality of arm parts extending from the main part toward the frame and configured to be bent three-dimensionally.

[2] The flexible wiring body according to the above [1], in which

the arm parts are bent to have a main surface that intersects with a main surface of the main part, and are further bent by folding back, and

the deformation of the arm parts provides freedom in rotations around axes in a horizontal direction and a vertical direction of the semiconductor element, and a direction perpendicular to a main surface of the semiconductor element.

[3] The flexible wiring body according to the above [1] or [2], in which

the number of the plurality of arm parts is four or more.

[4] The flexible wiring body according to any one of the above [1] to [3], in which in a plan view of the main part, the plurality of arm parts are disposed symmetrically with respect to the main part, and

the plurality of arm parts are bent by folding back to maintain a state where forces due to elastic deformation are balanced.

[5] The flexible wiring body according to any one of the above [1] to [4], in which

the arm parts include:
a first portion having a main surface substantially perpendicular to a main surface of the main part;
a second portion provided at one end of the first portion and bent by folding back;
a third portion disposed facing the first portion; and
a fourth portion provided at one end of the third portion and having a main surface substantially parallel to the main surface of the main part, and

the first portion, the second portion and the third portion are disposed substantially perpendicular to the main surface of the main part.

[6] The flexible wiring body according to any one of the above [1] to [5], in which

the arm parts include a resin layer and a plurality of linear conductive wires formed in parallel on the resin layer and insulated from each other.

[7] The flexible wiring body according to the above [6], in which

the plurality of arm parts have a total of 20 or more of the conductive wires.

[8] A driving system including:

an actuator configured to perform at least one among translations in three directions orthogonal to one another and rotations about axes in the three directions; and

the flexible wiring body according to any one of the above [1] to [7], in which

the actuator includes:
a base fixed to a substrate;
a movable portion mounted with the main part of the flexible wiring body and the semiconductor element; and
a plurality of springs connecting the base and the movable portion.

[9] The driving system according to the above [8], further including:

at least one displacement sensor configured to measure displacement of at least one of the movable portion and the plurality of springs.

The driving system according to the above [8], in which

the actuator is formed by MEMS.

[11] The driving system according to any one of the above [8] to [10], in which

the actuator is an electrostatic actuator.

[12] The driving system according to any one of the above [8] to [10], in which

the actuator is an electromagnetic actuator.

[13] The driving system according to the above [12], in which

the actuator is provided with a MEMS mounted on the substrate, and at least one coil provided within the substrate and electrically connected to an external circuit, and

the MEMS includes a base supported by the substrate, a movable portion fixed to the main part of the flexible wiring body and the semiconductor element, a plurality of springs connecting the base and the movable portion, and at least one magnetic body mounted to the movable portion.

The driving system according to the above [13], in which

the magnetic body is formed using a magnetic powder or a plated magnetic material, and is embedded in the movable portion.

The driving system according to the above [14], in which

the magnetic powder is bonded together by means of a deposited film or a resin binder.

[16] The driving system according to any one of the above [8] to [13], in which

the semiconductor element is an image sensor.

An imaging device includes the driving system according to the above [16], in which

the driving system is configured to perform one or both of optical image stabilization and focus adjustment by driving the image sensor.

### Advantageous Effect

According to the invention, it is possible to provide a flexible wiring body, a driving system, and an imaging device that can stably flow both a high-frequency signal for high-speed communication and a large current for driving an image sensor, can improve positioning performance of the imaging element mounted to an actuator, and can cope with large-scale production without requiring a complicated assembly process.

### BRIEF DESCRIPTION OF DRAWINGS

FIG. 1 is an exploded perspective view schematically showing a configuration of an imaging device according to an embodiment of the invention.

(a) of FIG. 2 is a plan view schematically showing a configuration of a driving system in FIG. 1, and (b) of FIG. 2 is a cross-sectional view taken along a line I-I′ in (a) of FIG. 2.

FIG. 3 is a partially enlarged cross-sectional view of (b) of FIG. 2.

FIG. 4 is a developed view of a flexible wiring body in (a) of FIG. 2.

(a) of FIG. 5 is a bottom view schematically showing a configuration of an actuator in (b) of FIG. 2, (b) of FIG. 5 is a schematic cross-sectional view taken along a line II-II′ in (a) of FIG. 5, and (c) of FIG. 5 is an enlarged cross-sectional view of an insulating portion in (b) of FIG. 5.

(a) of FIG. 6 is a plan view showing a modification of a driving system in (a) of FIG. 2, and (b) of FIG. 6 is a cross-sectional view taken along a line III-III′ in (a) of FIG. 6.

FIG. 7 is a partially enlarged cross-sectional view of (b) of FIG. 6.

FIG. 8 is a developed view of a flexible wiring body in (a) of FIG. 6.

FIG. 9 is a plan view showing another modification of a flexible wiring body in FIG. 4.

(a) of FIG. 10 is a partial plan view showing a state where a flexible wiring body of FIG. 9 is mounted on the actuator, and (b) of FIG. 10 is a partial cross-sectional view of (a) of FIG. 10.

FIG. 11 is a plan view showing another modification of the flexible wiring body in FIG. 4.

(a) of FIG. 12 is a partial plan view showing a state where a flexible wiring body of FIG. 11 is mounted on the actuator, and (b) of FIG. 12 is a partial cross-sectional view of (a) of FIG. 12.

FIG. 13 is a bottom view showing a modification of an actuator of FIG. 5.

FIG. 14 is a bottom view showing another modification of the actuator of FIG. 5.

FIG. 15 is a cross-sectional view showing a modification of the actuator in (b) of FIG. 2.

### DESCRIPTION OF EMBODIMENTS

Hereinafter, the embodiments of the invention will be described in detail with reference to drawings. In the drawings used in the following description, in order to facilitate understanding of features of the invention, the featured parts may be shown in an enlarged manner for convenience. Therefore, for example, dimensional ratios of the constituent elements may not be the same as the actual ones.

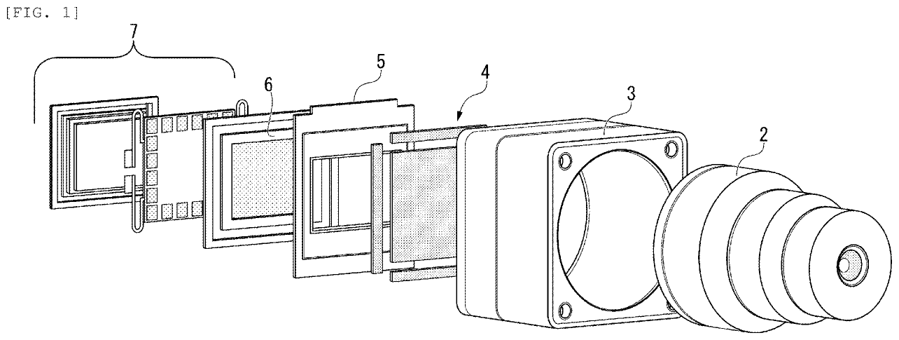

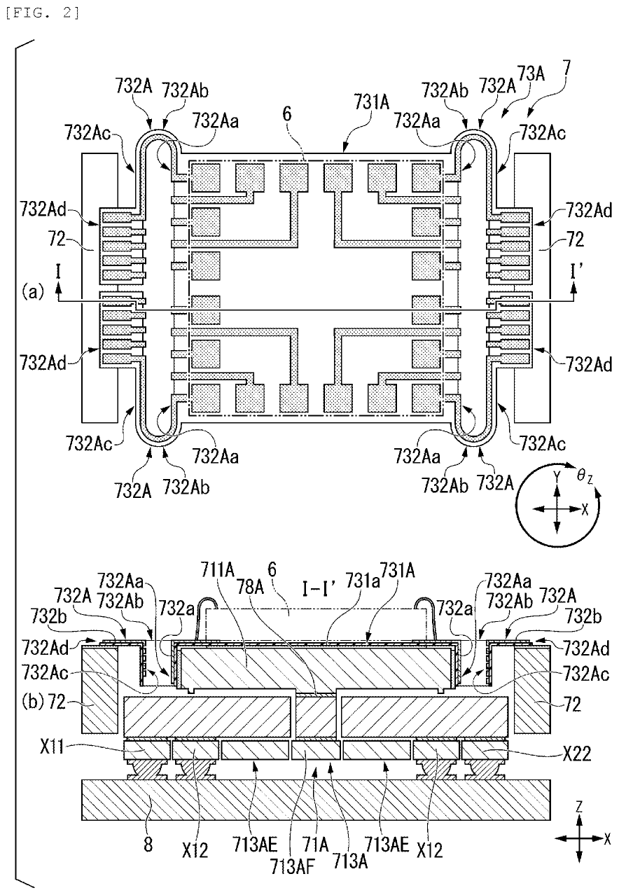

FIG. 1 is an exploded perspective view schematically showing a configuration of an imaging device according to an embodiment of the invention. As shown in FIG. 1, an imaging device 1 includes a lens 2, an AF unit 3, a glass member 4, a cover member 5, a semiconductor element 6, and a driving system 7. The imaging device 1 is not particularly limited, and for example, is a camera mounted on a mobile device such as a smartphone. The semiconductor element 6 is, for example, an image sensor. In the present embodiment, the driving system 7 performs one or both of optical image stabilization and focus adjustment by driving the semiconductor element 6 as an imaging element.

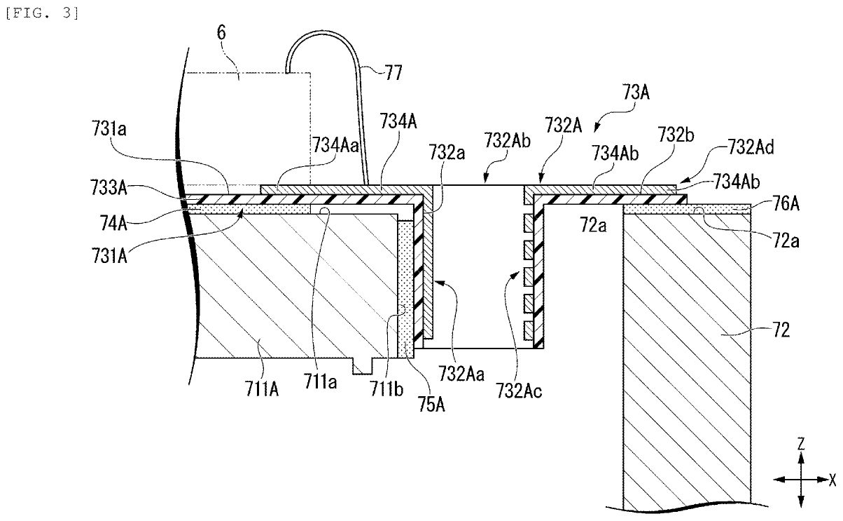

(a) of FIG. 2 is a plan view schematically showing a configuration of the driving system 7 in FIG. 1, (b) of FIG. 2 is a cross-sectional view taken along a line I-I′ in (a) of FIG. 2 and FIG. 3 is a partially enlarged cross-sectional view of (b) of FIG. 2.

The driving system 7 includes an actuator 71A that performs at least one among translations in three directions orthogonal to one another (for example, XYZ directions) and rotations about axes in the three directions, and a flexible wiring body 73A that connects the semiconductor element 6 and a frame 72 positioned outer than the semiconductor element 6. The semiconductor element 6 moves along with the actuator 71A. In the present embodiment, the actuator 71A performs movements including translations in the X direction and the Y direction, and rotation around an axis in the Z direction (ez direction) among the XYZ directions orthogonal to one another.

The flexible wiring body 73A is provided with a main part 731A mounted with the semiconductor element 6 and electrically connected to the semiconductor element 6, and a plurality of arm parts 732A extending from the main part 731A toward the frame 72 and bent three-dimensionally. In the present embodiment, the flexible wiring body 73A includes four arm parts 732A, and the four arm parts 732A are disposed line-symmetrically with respect to a line extending in the Y direction through a center of the main part 731A in the plan view, for example.

Each arm part 732A is bent to have a main surface 732a that intersects with a main surface 731a of the main part 731A ((b) of FIG. 2), and is further bent by folding back ((a) of FIG. 2). Deformation of the arm parts 732A provides freedom in rotations around the axes in a horizontal direction (X direction) and a vertical direction (Y direction) of the semiconductor element 6, and a direction perpendicular to a main surface of the semiconductor element 6 (Z direction).

The flexible wiring body 73A includes the four arm parts 732A, but the invention is not limited thereto, and may include four or more arm parts 732A. Further, it is preferable that in the plan view of the main part 731A, the plurality of arm parts 732A are disposed symmetrically with respect to the main part 731A, and the plurality of arm parts 732A are bent by folding back to maintain a state where forces due to elastic deformation are balanced. However, the forces due to the elastic deformation do not necessarily have to be balanced. The plurality of arm parts 732A may be disposed symmetrically with respect to the main part 731A, the plurality of arm parts 732A may be bent by folding back, and a state where no forces due to elastic deformation occur in any of the plurality of arm parts 732A may be maintained. Accordingly, a driving power of the actuator 71A can be reduced, and power saving can be achieved.

Specifically, each arm part 732A includes a first portion 732Aa having a main surface 732a substantially perpendicular to the main surface 731a of the main part 731A, a second portion 732Ab provided at one end of the first portion 732Aa and bent by folding back, a third portion 732Ac facing the first portion 732Aa, and a fourth portion 732Ad provided at one end of the third portion 732Ac and having a main surface 732b substantially parallel to the main surface 731a of the main part 731A. The first portion 732Aa, the second portion 732b and the third portion 732Ac are disposed substantially perpendicular to the main surface 731a of the main part 731A.

The main part 731A is fixed to an upper surface 711a of a stage portion 711A via an adhesive layer 74A. In addition, the first portion 732Aa of the arm part 732A is fixed to a side surface 711b of the stage portion 711A via an adhesive layer 75A, and the fourth portion 732Ad of the arm part 732A is fixed to an upper surface 72a of the frame 72 via an adhesive layer 76A (FIG. 3). The main part 731A moves along with the movements of the stage portion 711A in the X direction, the Y direction and/or the ez direction, and the second portion 732Ab and the third portion 732Ac of the arm part 732A are deformed due to the movement of the main part 731A.

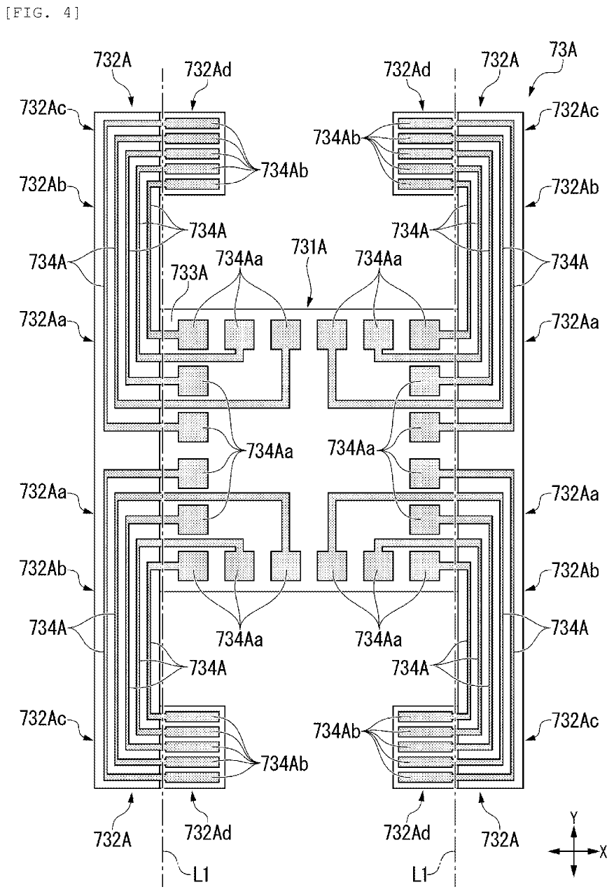

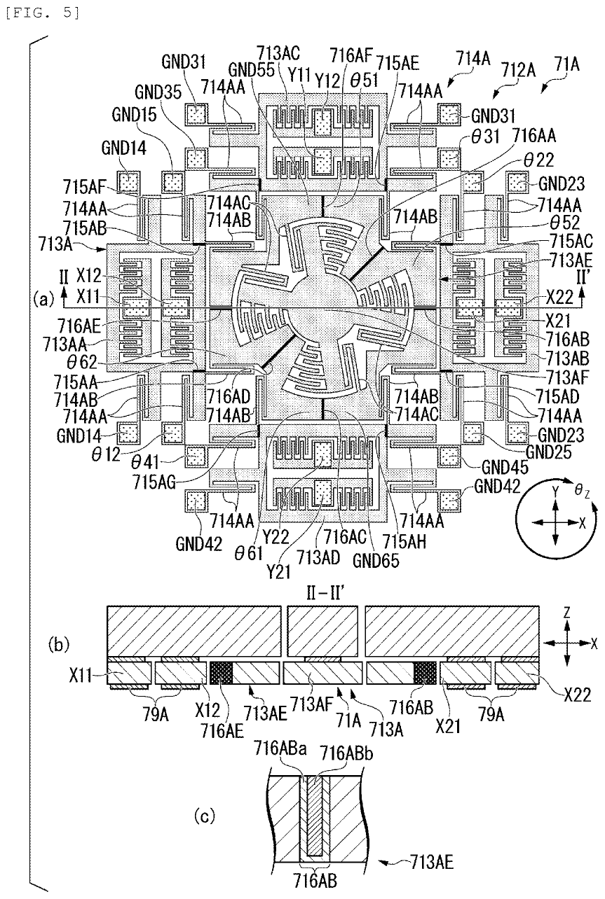

FIG. 4 is a developed view of the flexible wiring body 73A in (a) of FIG. 2. In the present embodiment, a three-dimensional structure as shown in (a) and (b) of FIG. 2 is formed by folding the flexible wiring body 73A as a mountain fold along lines L1, L1 in FIG. 4 and bending intermediate portions of the four arm parts 732A by folding back.

The flexible wiring body 73A includes a resin layer 733A and a plurality of linear conductive wires 734A formed in parallel on the resin layer 733A and insulated from each other. That is, the main part 731A and the arm parts 732A are formed by the resin layer 733A and the plurality of linear conductive wires 734A formed in parallel on the resin layer 733A and insulated from each other. The resin layer 733A may include a single layer, or may include a plurality of layers made of different materials. Each of the plurality of conductive layers 734A may also include a single layer, or may include a plurality of layers made of different materials. The conductive layer 734A has one end portion 734Aa electrically connected to the semiconductor element 6 via a wire portion 77 such as a bonding wire made of a metal, and the other end portion 734Ab electrically connected to a connector terminal (not shown) (FIG. 3). A thickness of the resin layer 733A is, for example, 10 μm to 30 μm, and a thickness of the conductive layer 734A is, for example, 5 μm to 15 μm. The resin layer 733A is made of, for example, polyimide (PI), and the conductive layer 734A is made of, for example, copper (Cu). Although the conductive layer includes a single layer in FIG. 3, the conductive layer may include a plurality of layers to perform more complicated wiring. Further, an insulating protective layer may be formed on the conductive layer. In addition, although only the semiconductor element 6 is mounted on the flexible wiring body 73A in FIG. 3, other elements may be mounted as well.

The plurality of arm parts 732A preferably have a total of 20 or more of the conductive wires 734A. In the present embodiment, each arm part 732A is provided with five conductive wires 734A, and the plurality of arm parts 732A have a total of 20 conductive wires 734A. However, as long as a total of 20 or more of the conductive wires 734A are provided, the number of the arm parts and the number of the conductive wires of each arm part are not limited and can be appropriately changed according to specifications. Accordingly, it is possible to sufficiently cope with an increase in the number of wires due to high functionality of the semiconductor element 6 or the like. In the present embodiment, line widths of the 20 conductive wires 734A in the plan view are the same, but the invention is not limited thereto, and the line widths of the 20 conductive wires 734A may be different. For example, the plurality of conductive wires 734A may include a conductive wire for communication that has a small width and a conductive wire for power that has a large width. Accordingly, in the plurality of conductive wires 734A, a conductive layer through which a high frequency signal for high-speed communication flows and a conductive wire through which a large current for driving the imaging element flows can be provided, and both the high frequency signal for high-speed communication and the large current for driving the imaging element can flow through the flexible wiring body 73A.

A method of forming the flexible wiring body 73A is not particularly limited, and the flexible wiring body 73A can be formed by, for example, a subtractive method of forming a circuit by etching a copper foil of a copper laminate, or a semi-additive method of forming a circuit on an insulating base material having a conductive layer by an electrolytic copper plating process.

(a) of FIG. 5 is a bottom view schematically showing a configuration of the actuator 71A in (b) of FIG. 2, (b) of FIG. 5 is a schematic cross-sectional view taken along a line II-II′ in (a) of FIG. 5, and (c) of FIG. 5 is an enlarged cross-sectional view of an insulating portion in (b) of FIG. 5. In the present embodiment, the actuator 71A is an electrostatic actuator.

The actuator 71A includes a plurality of bases 712A fixed to a substrate 8, a movable portion 713A mounted with the main part 731A of the flexible wiring body 73A and the semiconductor element 6 via the stage portion 711A, and a plurality of springs 714A connecting the bases 712A and the movable portion 713A. As long as the actuator 71A includes the bases 712A, the movable portion 713A and the plurality of springs 714A, the form thereof is not limited, and the actuator 71A is formed by, for example, MEMS from the viewpoint of miniaturization and ease of manufacture.

Specifically, the plurality of bases 712A include fixing portions X11, X12, GND14, GND15, GND14, and 812 disposed on one end side of the actuator 71A with respect to the X direction, and fixing portions X21, X22, 822, GND23, GND25, and GND23 disposed on the other end side of the actuator 71A with respect to the X direction. The symbol “X” of the fixing portions indicates a portion where a voltage is applied when the movable portion 713A is to be translated in the X direction, the symbol “GND” indicates a portion to be grounded, and the symbol “θ” indicates a portion where a voltage is applied when the movable portion 713A is to be rotated in the θz direction. The fixing portions X11 and X12 are connected to the substrate 8 via an extraction electrode 79A. Since the other fixing portions have the same configuration, the description thereof will be omitted.

The two fixing portions X11, X12 are formed with comb teeth of one side of a comb electrode, and comb teeth of the other side are formed in a first movable portion 713AA to be described later. The four fixing portions GND14, GND14, GND15, and θ12 are respectively connected to the first movable portion 713AA to be described later via a first spring 714AA. Further, the two fixing portions X21, X22 are each formed with comb teeth of one side of a comb electrode, and comb teeth of the other side are formed in a first movable portion 713AB to be described later. The four fixing portions θ22, GND23, GND25, and GND23 are each connected to the first movable portion 713AB to be described later via the first spring 714AA.

In addition, the plurality of bases 712A include fixing portions Y11, Y12, GND31, GND35, GND31, and θ31 disposed on one end side of the actuator 71A with respect to the Y direction, and fixing portions Y21, Y22, θ41, GND42, GND45, and GN42 disposed on the other end side of the actuator 71A with respect to the Y direction. The symbol “Y” of the fixing portions indicates a portion where a voltage is applied when the movable portion 713A is to be moved in the Y direction, the symbol “GND” indicates a portion to be grounded, and the symbol “θ” indicates a portion where a voltage is applied when the movable portion 713A is to be rotated in the θz direction.

The two fixing portions Y11, Y12 are formed with comb teeth of one side of a comb electrode, and comb teeth of the other side are formed in a first movable portion 713AC to be described later. The four fixing portions GND31, GND35, GND31, and θ31 are each connected to the first movable portion 713AC to be described later via the first spring 714AA. Further, the two fixing portions Y21, Y22 are each formed with comb teeth of one side of a comb electrode, and comb teeth of the other are formed in a first movable portion 713AD to be described later. The four fixing portions θ22, GND23, GND25, and GND23 are each connected to the first movable portion 713AD to be described later via the first spring 714AA.

The movable portion 713A includes the four first movable portions 713AA, 713AB, 713AC and 713AD which are disposed at four sides (XY directions) of a second movable portion to be described later, a second movable portion 713AE disposed in the centers of the four first movable portions 713AA to 713AD, connected to the four first movable portions 713AA to 713AD via a plurality of second springs 714AB, and having a substantially cross shape in the plan view, and a third movable portion 713AF disposed in a center of the second movable portion 713AE, connected to the second movable portion 713AE via a plurality of third springs 714AC, and having a substantially X shape in the plan view.

The first movable portions 713AA, 713AB, 713AC and 713AD are, for example, frames having a substantially double cross shape in the plan view. The fixing portions GND14, GND15, GND14, and 812 are disposed on both sides of the first movable portion 713AA in the Y direction, and the fixing portions X11 and X12 are disposed on an inner side of the first movable portion 713AA. Further, the fixing portions 822, GND23, GND25, and GND23 are disposed on both sides of the first movable portion 713AB in the Y direction, and the fixing portions X21 and X22 are disposed on an inner side of the first movable portion 713AB. Similarly, the fixing portions GND31, GND35, GND31, and 831 are disposed on both sides of the first movable portion 713AC in the X direction, and the fixing portions Yll and Y12 are disposed on an inner side of the first movable portion 713AC. Further, the fixing portions θ41, GND42, GND45, and GND42 are disposed on both sides of the first movable portion 713AD in the X direction, and the fixing portions Y21 and Y22 are disposed on an inner side of the first movable portion 713AD.

The fixing portions GND14, GND15, GND14, and θ12 are each connected to the first movable portion 713AA via the first spring 714AA. The fixing portions 022, GND23, GND25, and GND23 are each connected to the first movable portion 713AB via the first spring 714AA. The fixing portions GND31, GND35, GND31, and 031 are each connected to the first movable portion 713AC via the first spring 714AA. The fixing portions θ41, GND42, GND45, and GND42 are each connected to the first movable portion 713AD via the first spring 714AA. In addition, the plurality of first springs 714AA also function as an electrical connection portion in addition to functioning as a mechanical connection portion.

The first movable portion 713AA is provided with insulating portions 715AA and 715AB for insulating the fixing portion GND14 from the fixing portions θ12 and GND15. The first movable portion 713AB is provided with insulating portions 715AC and 715AD for insulating the fixing portion GND23 from the fixing portions θ22 and GND25. The first movable portion 713AC is provided with insulating portions 715AE and 715AF for insulating the fixing portion GND31 from the fixing portions 031 and GND35. The first movable portion 713AD is provided with insulating portions 715AG and 715AH for insulating the fixing portion GND42 from the fixing portions θ41 and GND45. The above insulating portions are formed of, for example, a single layer or a plurality of layers made of a material such as silicon nitride (SiN) or polysilicon (p-Si), and is formed by trench isolation or the like.

In the present embodiment, the fixing portion X11 has the same potential as the fixing portion X21, and the fixing portion X12 has the same potential as the fixing portion X22. The fixing portion Yll has the same potential as the fixing portion Y21, and the fixing portion Y12 has the same potential as the fixing portion Y22. When a voltage is applied to the fixing portions X11 and X21, the first movable portions 713AA and 713AB move in one side in the X direction (for example, +X direction), and when a voltage is applied to the fixing portions X12 and X22, the first movable portions 713AA and 713AB move in the other side in the X direction (for example, −X direction). On the other hand, when a voltage is applied to the fixing portions Y11 and Y21, the first movable portions 713AC and 713AD move in one side in the Y direction (for example, +Y direction), and when a voltage is applied to the fixing portions Y12 and Y22, the first movable portions 713AC and 713AD move in the other side in the Y direction (for example, −Y direction).

The second movable portion 713AE is, for example, a frame-shaped body having a substantially cross-shaped outline in the plan view, and is connected to the four first movable portions 713AA, 713AB, 713AC, and 713AD via the eight second springs 714AB. Two of the second springs 714AB are disposed on one end side of the second movable portion 713AE in the X direction, and two of the second springs 714AB are disposed on the other end side thereof. Further, two of the second springs 714AB are disposed on one end side of the second movable portion 713AE in the Y direction, and two of the second springs 714AB are disposed on the other end side thereof. The second springs 714AB are designed such that the second movable portion 713AE moves in one direction (one of X direction and Y direction).

The second movable portion 713AE is formed with comb teeth constituting one sides of a plurality of comb electrodes, and comb teeth constituting the other sides of the plurality of comb electrodes are formed at the third movable portion 713AF. In the present embodiment, four comb electrodes are disposed between the second movable portion 713AE and the third movable portion 713AF to be rotationally symmetric by 180 degrees with respect to a center of the third movable portion 713AF.

The second movable portion 713AE includes six moving portions 851, 852, GND55, 861, 862, and GND65 provided to surround the third movable portion 713AF. The moving portions 851, 852, GND55, 861, 862, and GND65 are disposed to be rotationally symmetric by 180 degrees with respect to the center of the third movable portion 713AF. The symbol “GND” of the moving portions indicates a portion to be grounded, and the symbol “θ” indicates a portion where a voltage is applied when the second movable portion 713AE is to be rotated in the 8z direction.

The moving portion θ51 is connected to the fixing portion 831 via the second spring 714AB and the first spring 714AA. The moving portion 852 is connected to the fixing portion 822 via the second spring 714AB and the first spring 714AA. The moving portion GND55 is connected to the fixing portions GND15 and GND35 via the second spring 714AB and the first spring 714AA, respectively. The moving portion θ61 is connected to the fixing portion θ41 via the second spring 714AB and the first spring 714AA. The moving portion θ62 is connected to the fixing portion θ12 via the second spring 714AB and the first spring 714AA. The moving portion GND65 is connected to the fixing portions GND25 and GND45 via the second spring 714AB and the first spring 714AA, respectively. In addition, the plurality of second springs 714AB and first springs 714AA also function as an electrical connection portion in addition to functioning as a mechanical connection portion.

Insulating portions 716AA, 716AB, 716AC, 716AD, 716AE, and 716AF are provided between adjacent moving portions of the six moving portions θ51, θ52, GND55, θ61, θ62, and GND65. The above insulating portions include, for example, a single layer or a plurality of layers made of a material such as SiN or p-Si, and is formed by trench isolation or the like. In the present embodiment, as shown in (c) of FIG. 5, the insulating portion 716AB includes a first layer 716ABa made of SiN and a second layer 716ABb made of p-Si. Since the insulating portions 716AA and 716AC to 716AF have the same configuration as the insulating portion 716AB, the description thereof will be omitted.

The third movable portion 713AF is, for example, a frame-shaped body having a substantially X shape in the plan view, and is connected to the second movable portion 713AE via the plurality of third springs 714AC. The plurality of third springs 714AC also function as an electrical connection portion in addition to functioning as a mechanical connection portion. One end side of the third movable portion 713AF in the X direction is provided with a third spring 714AC, and the other end side thereof is also provided with a third spring 714AC. Further, one end side of the third movable portion 713AF in the Y direction is provided with a third spring 714AC, and the other end side thereof is also provided with a third spring 714AC. In the present embodiment, the four third springs 714AC are disposed to be line-symmetric with respect to a line corresponding to y=x or y=−x with the center of the third movable portion 713AF as an origin. The third movable portion 713AF is fixed to the stage portion 711A via an adhesive layer 78A ((b) of FIG. 2).

In the present embodiment, the moving portion θ51 has the same potential as the fixing portion θ31, and the moving portion θ52 has the same potential as the fixing portion θ22. The moving portion θ61 has the same potential as the fixing portion θ41, and the moving portion θ62 has the same potential as the fixing portion θ12. Further, the moving portions GND55 and GND65 have the same potential as the fixing portions GND35 and GND45. When the same voltage is applied to the moving portions θ51 and θ61, the third movable portion 713AF moves to one side in the θz direction (for example, clockwise), and when the same voltage is applied to the moving portions θ52 and θ62, the third movable portion 713AF moves to the other side in the θz direction (for example, counterclockwise).

By applying a voltage to the predetermined fixing portions and/or moving portions as described above, the first movable portions 713AA to 713AD and the second movable portion 713AE translate in the X direction and/or the Y direction, and the third movable portion 713AF rotates in the θz direction. Therefore, the third movable portion 713AF moves in the X direction, the Y direction and/or the θz direction. The stage portion 711A moves in the X direction, the Y direction and/or the θz direction in accordance with the movements of the third movable portion 713AF, and the main part 731A of the flexible wiring body 73A moves in the X direction, the Y direction and/or the θz direction in accordance with the movements of the stage portion 711A. The plurality of arm parts 732A of the flexible wiring body 73A are easily deformed in accordance with the movements of the main part 731A and follow the movements of the main part 731A.

A method of forming the actuator 71A is not particularly limited, and the actuator 71A can be formed by, for example, using a substrate such as an SOI in which silicon single crystals are formed on both sides of an oxide film, and performing etching such as deep reactive ion etching (DRIE) on a handle layer and an active layer. The insulating portions in the actuator 71A may be formed by combining DRIE, LPCVD, polishing, and the like.

The driving system 7 may include at least one displacement sensor for measuring displacement of at least one of the movable portions and the plurality of springs. For example, in order to measure displacement of the third movable portion 713AF, the driving system 7 may use a driving comb electrode, or may further include another displacement sensor. By inputting a signal from the displacement sensor to a control unit (not shown) and controlling driving of the actuator 71A based on the signal, it is possible to achieve highly accurate position control of the semiconductor element 6.

As described above, according to the present embodiment, the flexible wiring body 73A includes the main part 731A mounted with the semiconductor element 6 and electrically connected to the semiconductor element 6, and the plurality of arm parts 732A extending from the main part 731A toward the frame 72 and bent three-dimensionally. Therefore, the main surfaces 732a of the plurality of arm parts 732A formed integrally with the main part 731A are not parallel to the main surface 731a of the main part 731A, the plurality of arm parts 732A are easily and sufficiently bent in an out-of-plane direction with respect to the translation (X direction and/or Y direction) or the rotation (θz direction) of the main part 731A fixed to the stage portion 711A, and the movements of the actuator 71A are less likely to be inhibited. As a result, positioning performance of the semiconductor element 6 mounted on the main part 731A can be improved. In addition, since the conductive wires for communication and the conductive wires for power are provided on the arm parts 732A, both of the high-frequency signal for high-speed communication and the large current for driving the image sensor can flow stably. Further, since the flexible wiring body 73A can be formed by performing a simple bending process on the flexible wiring body 73A in a developed state, it is possible to cope with large-scale production without requiring a complicated assembly process.

Further, in the plan view of the main part 731A, the plurality of arm parts 732A are disposed symmetrically with respect to the main part 731A, and the plurality of arm parts 732A are bent by folding back to maintain the state where the forces due to elastic deformation are balanced. Therefore, a resistance force due to rigidity of the flexible wiring body 73A is reduced, and thus the movements of the actuator 71A is less likely to be inhibited and the movement of the semiconductor element 6 with high accuracy can be achieved even when the actuator 71A is formed by a MEMS or the like and the generated force is small.

Further, in the arm part 732A, the first portion 732Aa having the main surface 732a substantially perpendicular to the main surface 731a of the main part 731A, the second portion 732Ab provided at one end of the first portion 732Aa and bent by folding back, and the third portion 732Ac facing the first portion 732Aa are disposed substantially perpendicular to the main surface 731a of the main part 731A, so that the plurality of arm parts 732A can reliably follow the translation (in X direction and/or Y direction) and the rotation (in θz direction) of the main part 731A fixed to the stage portion 711A, the positioning performance of the semiconductor element 6 mounted on the main part 731A can be further improved, and connection reliability can be improved.

In addition, according to the present embodiment, the actuator 71A is formed with the plurality of insulating portions 715AA to 715AF and 716AA to 716AF, and is provided with a driving mechanism and a circuit for performing the translation in the X direction, a driving mechanism and a circuit for performing the translation in the Y direction, and a driving mechanism and a circuit for performing the rotation in the ez direction, which are electrically independent of one another. Therefore, free movement in the X direction, the Y direction and/or the θz direction can be achieved. Since the driving circuits of the actuator 71A are connected to a circuit (not shown) of the substrate 8, a wire of the actuator 71A and a wire of the semiconductor element 6 (conductive layer of the flexible wiring body 73A) can be separately formed above and below the stage portion 711A, and physical interference between these wires can be reliably prevented. Further, by flip-chip connecting the plurality of bases 712A of the actuator 71A to the substrate 8, it is possible to protect a fine portion of the movable portion 713A of the actuator 71A.

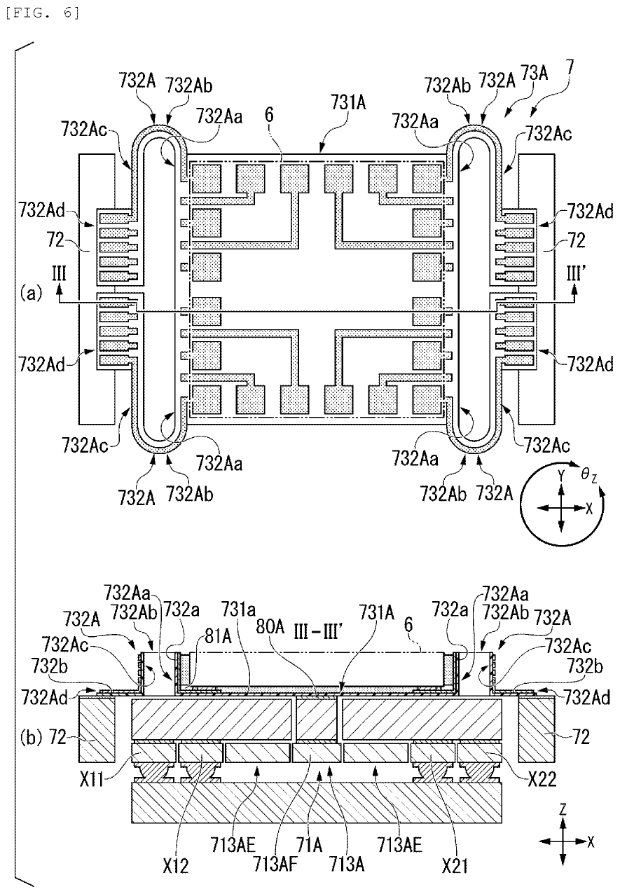

(a) of FIG. 6 is a plan view showing a modification of the driving system 7 in (a) of FIG. 2, (b) of FIG. 6 is a cross-sectional view taken along a line III-III′ in (a) of FIG. 6, and FIG. 7 is a partially enlarged cross-sectional view of (b) of FIG. 6. The configuration of the driving system in (a) of FIG. 6 is mainly different from that of the driving system 7 in (a) of FIG. 2 in that the driving system does not include the stage portion 711A and the actuator 71A is directly connected to the flexible wiring body 73A via an adhesive layer 80A. The same constituent elements as those of the driving system 7 in (a) of FIG. 2 are denoted by the same reference numerals, and the description thereof will be omitted.

The flexible wiring body 73A in (a) of FIG. 6 has the same configuration as the flexible wiring body 73A in (a) of FIG. 2 in the developed state, and has a configuration different from that of the flexible wiring body 73A in (a) of FIG. 2 in a state where the three-dimensional structure is formed by processing. As shown in (b) of FIG. 6, the flexible wiring body 73A is defined by the main part 731A and the arm parts 732A, and has an accommodation portion 81A in which the semiconductor element 6 is accommodated. As shown in FIG. 7, the main part 731A is fixed to a lower surface 6a of the semiconductor element 6 via an adhesive layer 82A. The first portion 732Aa of the arm part 732A is fixed to a side surface 6b of the semiconductor element 6 via an adhesive layer 83A (FIG. 7). In addition, the end portion 734Aa of the conductive layers 734A is electrically connected to the semiconductor element 6 via a joint portion 84A formed by ultrasonic connection, thermocompression bonding, connection using a conductive adhesive material, or the like, and the other end portion 734Ab is electrically connected to the connector terminal (not shown).

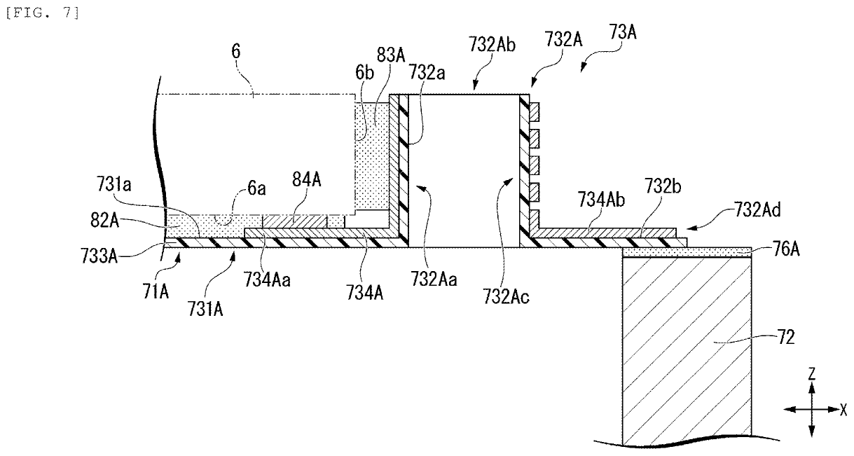

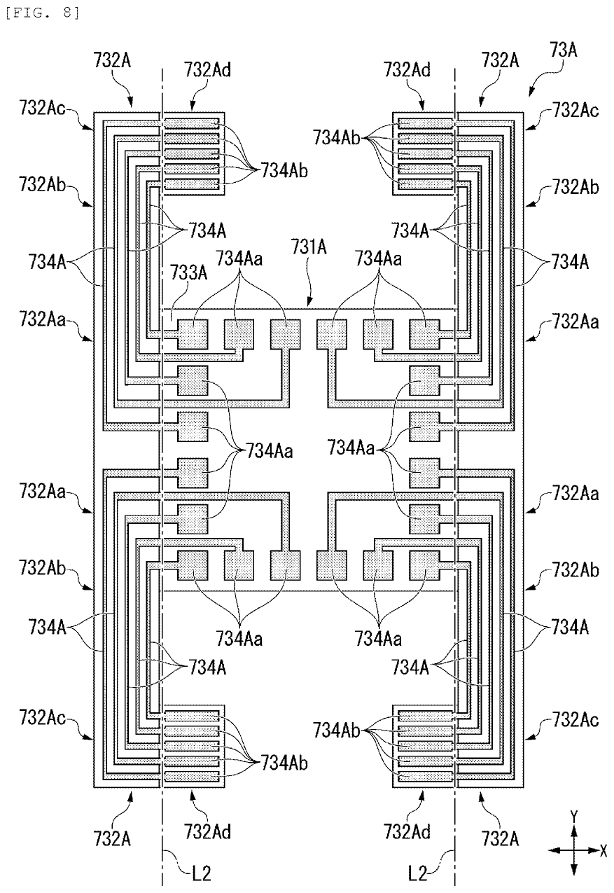

FIG. 8 is a developed view of the flexible wiring body 73A in (a) of FIG. 6. In the present modification, a three-dimensional structure as shown in (a) and (b) of FIG. 6 is formed by folding the flexible wiring body 73A as a mountain fold along lines L2, L2 in FIG. 8 and bending intermediate portions of the four arm parts 732A by folding back.

As described above, according to the present modification, the flexible wiring body 73A can also be applied to the driving system 7 without the stage portion 711A. That is, the flexible wiring body 73A includes the main part 731A mounted with the semiconductor element 6 and electrically connected to the semiconductor element 6, and the plurality of arm parts 732A extending from the main part 731A toward the frame 72 and bent three-dimensionally. Therefore, the main surfaces 732a of the plurality of arm parts 732A formed integrally with the main part 731A are not parallel to the main surface 731a of the main part 731A, the plurality of arm parts 732A are easily and sufficiently bent in an out-of-plane direction with respect to the translation (the X direction and/or the Y direction) or the rotation (the ez direction) of the main part 731A fixed to the stage portion 711A, and the movements of the actuator 71A are less likely to be inhibited. As a result, the positioning performance of the semiconductor element 6 mounted on the main part 731A can be improved. Since the semiconductor element 6 and the flexible wiring body 73A are electrically connected by providing the joint portion 84A without providing the wire portion, it is possible to contribute to a reduction in height of the combined configuration of the semiconductor element 6 and the driving system 7.

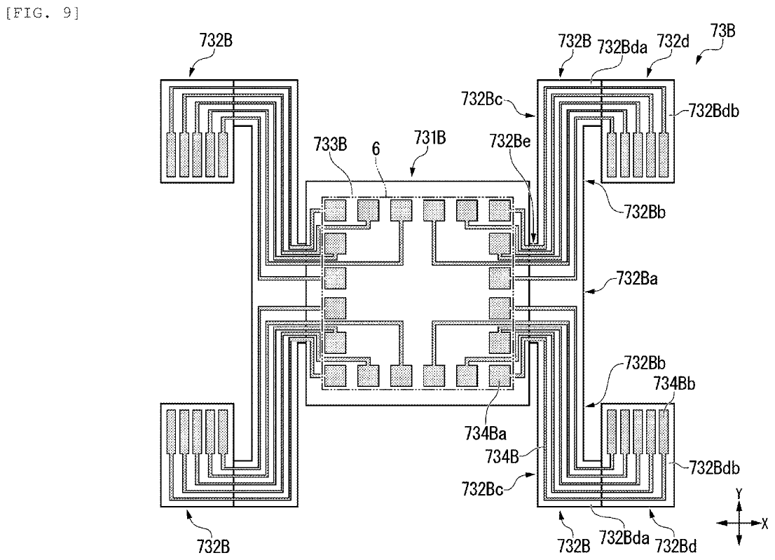

FIG. 9 is a plan view showing another modification of the flexible wiring body in FIG. 4. (a) of FIG. 10 is a partial plan view showing a state where the flexible wiring body of FIG. 9 is mounted on the actuator, and (b) of FIG. 10 is a partial cross-sectional view of (a) of FIG. 10. The configuration of the flexible wiring body of FIG. 9 is different from that of the flexible wiring body of FIG. 4 in the shape of the arm part.

As shown in FIG. 9, a flexible wiring body 73B includes a main part 731B mounted with the semiconductor element 6 and electrically connected to the semiconductor element 6, and a plurality of arm parts 732B extending from the main part 731B toward the frame 72 (see (a) and (b) of FIG. 2) and bent three-dimensionally.

As shown in (a) and (b) of FIG. 10, each arm part 732B includes a first portion 732Ba having a main surface 732c substantially perpendicular to a main surface 731b of the main part 731B, a second portion 732Bb provided at one end of the first portion 732Ba and bent by folding back, a third portion 732Bc facing the first portion 732Ba, and a fourth portion 732Bd provided at one end of the third portion 732Bc and having main surface 732d substantially parallel to the main surface 731b of the main part 731B. The first portion 732Ba, the second portion 732Bb, and the third portion 732Bc are disposed substantially perpendicular to the main surface 731b of the main part 731B ((b) of FIG. 10).

The fourth portion 732Bd includes an extension portion 732Bda disposed perpendicular to the third portion 732Bc and an extension portion 732Bdb disposed perpendicular to the extension portion 732Bda (FIG. 9). In a state where the flexible wiring body 73B is mounted on the actuator 71A ((a) of FIG. 10), the extension portion 732Bda extends in a direction away from the main part 731B (X direction) in the plan view, and the extension portion 732Bdb extends from the extension portion 732Bda in the horizontal direction (Y direction). The two extension portions 732Bdb provided in the two adjacent arm parts 732B extend in the horizontal direction (Y direction) and extend in directions away from each other. Further, in the present modification, the fourth portion 732Bd is provided on a plane different from the main part 731B, and is disposed below the main part 731B.

In the present modification, the other end portion 734Bb of a conductive layer 734B is provided at the extension portion 732Bdb, one end portion 734Ba of the conductive layer 734B is electrically connected to the semiconductor element 6, and the other end portion 734Bb is electrically connected to a connector terminal (not shown). In a state where the flexible wiring body 73B is bent three-dimensionally, the other end portion 734Bb of the conductive layer 734B is disposed on a lower side (back side) of a resin layer 733B with respect to the Z direction ((b) of FIG. 10).

The arm part 732B may have a fifth portion 732Be serving as a margin portion at the time of bending between the main part 731B and the first portion 732Ba (FIG. 9). A dimension in a width direction (Y direction) of the fifth portion 732Be is preferably smaller than a dimension in a width direction of the main part 731B. Accordingly, the first portion 732Ba can be easily formed by bending process, buckling of the conductive layer 734B at a bent portion can be prevented, and electrical connection reliability of the conductive layer 734B can be further improved.

According to the present modification, since the fourth portion 732Bd includes the extension portion 732Bda disposed perpendicular to the third portion 732Bc and the extension portion 732Bdb disposed perpendicular to the extension portion 732Bda, it is possible to improve flexibility in designing the fourth portion 732Bd to be inserted into the connector terminal.

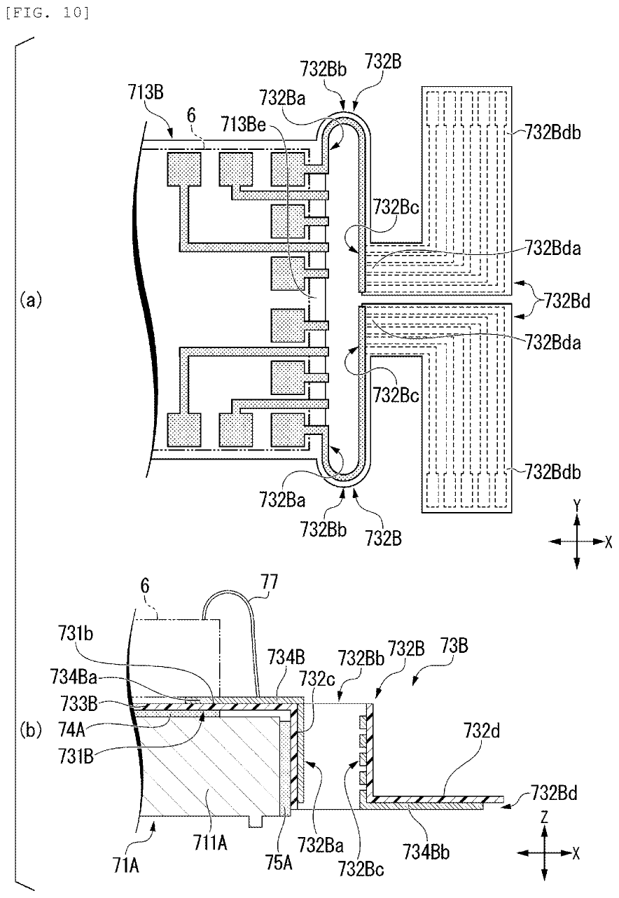

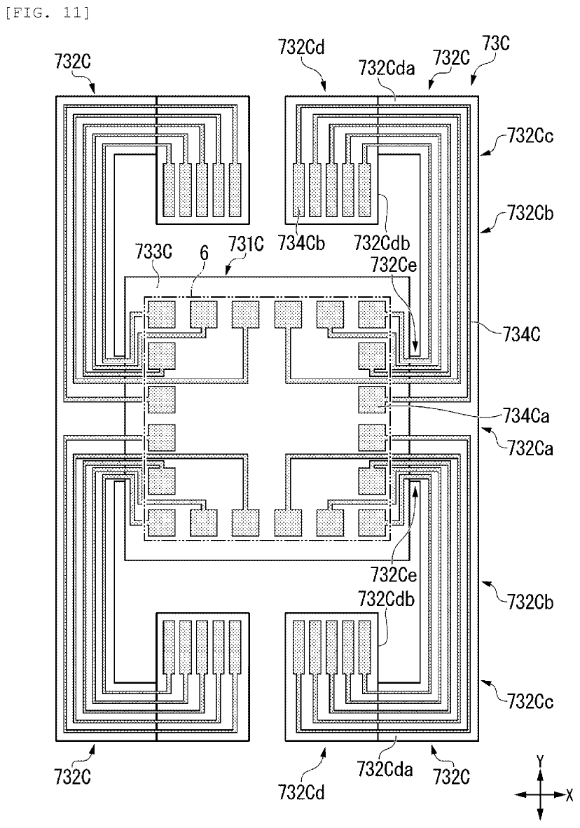

FIG. 11 is a plan view showing another modification of the flexible wiring body in FIG. 4. (a) of FIG. 12 is a partial plan view showing a state where the flexible wiring body of FIG. 11 is mounted on the actuator, and (b) of FIG. 12 is a partial cross-sectional view of (a) of FIG. 12.

As shown in FIG. 11, a flexible wiring body 73C includes a main part 731C mounted with the semiconductor element 6 and electrically connected to the semiconductor element 6, and a plurality of arm parts 732C extending from the main part 731C toward the frame 72 (see (a) and (b) of FIG. 2) and bent three-dimensionally.

As shown in (a) and (b) of FIG. 12, each arm part 732C includes a first portion 732Ca having a main surface 732e substantially perpendicular to a main surface 731c of the main part 731C, a second portion 732Cb provided at one end of the first portion 732Ca and bent by folding back, a third portion 732Cc facing the first portion 732Ca, and a fourth portion 732Cd provided at one end of the third portion 732Cc and having a main surface 732f substantially parallel to the main surface 731c of the main part 731C. The first portion 732Ca, the second portion 732Cb and the third portion 732Cc are disposed substantially perpendicular to the main surface 731c of the main part 731C ((b) of FIG. 10).

The fourth portion 732Cd includes an extension portion 732Cda disposed perpendicular to the third portion 732Cc and an extension portion 732Cdb disposed perpendicular to the extension portion 732Cda (FIG. 11). In a state where the flexible wiring body 73C is mounted on the actuator 71A ((a) of FIG. 12), the extension portion 732Cda extends in a direction away from the main part 731C (X direction) in the plan view, and the extension portion 732Cdb extends from the extension portion 732Cda in the horizontal direction (Y direction). The two extension portions 732Cdb provided in the two adjacent arm parts 732C extend in the horizontal direction (Y direction) and extend in directions away from each other. In the present modification, the fourth portion 732Cd is provided on the same plane as the main part 731C.

In the present modification, the other end portion 734Cb of a conductive layer 734C is provided at the extension portion 732Cdb, one end portion 734Ca of the conductive layer 734C is electrically connected to the semiconductor element 6, and the other end portion 734Cb is electrically connected to a connector terminal (not shown). In a state where the flexible wiring body 73C is bent three-dimensionally, the other end portion 734Cb of the conductive layer 734C is disposed on an upper side (front side) of a resin layer 733C with respect to the Z direction ((b) of FIG. 12).

According to the present modification, since the fourth portion 732Cd includes the extension portion 732Cda disposed perpendicular to the third portion 732Cc and the extension portion 732Cdb disposed perpendicular to the extension portion 732Cda, it is possible to improve flexibility in designing the fourth portion 732Cd to be inserted into the connector terminal in the same manner as the fourth portion 732Bd of the flexible wiring body 73B.

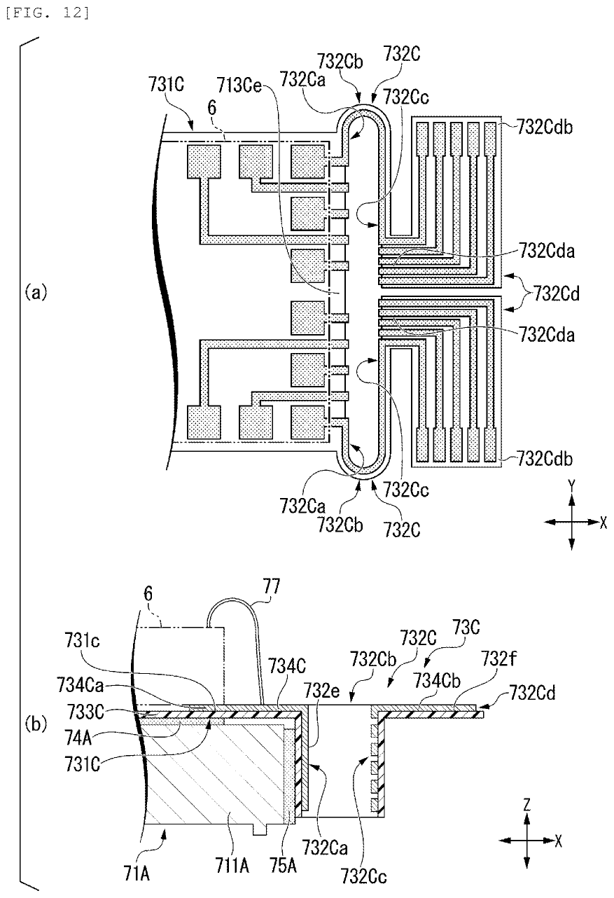

FIG. 13 is a bottom view showing a modification of the actuator 71A of FIG. 5.

As shown in FIG. 13, an actuator 71B includes a plurality of bases 712B fixed to the substrate 8 (see (b) of FIG. 2), a movable portion 713B mounted with the main part 731A of the flexible wiring body 73A and the semiconductor element 6, and a plurality of springs 714B connecting the bases 712B and the movable portion 713B. Similar to the actuator 71A, the actuator 71B is formed by, for example, MEMS.

The plurality of bases 712B include fixing portions X31, X32, GND51, and GND51 disposed on one end side of the actuator 71B with respect to the X direction, and fixing portions X41, X42, GND51, and GND51 disposed on the other end side of the actuator 71B with respect to the X direction. The fixing portions X31 and X32 are connected to the substrate 8 via an extraction electrode (not shown) (see (b) of FIG. 5). Since the other fixing portions have the same configuration, the description thereof will be omitted.

The two fixing portions X31 and X32 are formed with comb teeth of one side of a comb electrode, and comb teeth of the other side are formed in a first movable portion 713BA to be described later. The two fixing portions GND51 and GND51 are each connected to the first movable portion 713BA to be described later via first springs 714BA. Further, the two fixing portions X41, X42 are each formed with comb teeth of one side of a comb electrode, and comb teeth of the other side are formed in a first movable portion 713BB to be described later. The two fixing portions GND51 and GND51 are each connected to the first movable portion 713BB to be described later via first springs 714BA.

In addition, the plurality of bases 712B include fixing portions Y31, Y32, GND51 and GND51 disposed on one end side of the actuator 71B with respect to the Y direction, and fixing portions Y41, Y42, GND51, and GND51 disposed on the other end side of the actuator 71B with respect to the Y direction.

The two fixing portions Y31 and Y32 are formed with comb teeth of one side of a comb electrode, and comb teeth of the other side are formed in a first movable portion 713BC to be described later. The two fixing portions GND51 and GND51 are each connected to the first movable portion 713BC to be described later via first springs 714BA. The two fixing portions Y41 and Y42 are each formed with comb teeth of one side of a comb electrode, and comb teeth of the other side are formed in a first movable portion 713BD to be described later. The two fixing portions GND51 and GND51 are each connected to the first movable portion 713BD to be described later via first springs 714BA.

The movable portion 713B includes the four first movable portions 713BA, 713BB, 713BC, and 713BD disposed at four sides (XY directions) of a second movable portion to be described later, and a second movable portion 713BE disposed in a center of the four first movable portions 713BA to 713BD, connected to the four first movable portions 713BA to 713BD via a plurality of second springs 714BB, and having a substantially windmill shape in the plan view.

The first movable portions 713BA, 713BB, 713BC and 713BD are, for example, frames having a substantially double cross shape in the plan view. The fixing portions GND51 and GND51 are disposed on both sides of the first movable portion 713BA in the Y direction, and the fixing portions X31 and X32 are disposed on an inner side of the first movable portion 713BA. Similarly, the fixing portions GND51 and GND51 are disposed on both sides of the first movable portion 713BB in the Y direction, and the fixing portions X41 and X42 are disposed on an inner side of the first movable portion 713BB.

Further, the fixing portions GND51 and GND51 are disposed on both sides of the first movable portion 713BC in the X direction, and the fixing portions Y31 and Y32 are disposed on an inner side of the first movable portion 713BC. The fixing portions GND51 and GND51 are disposed on both sides of the first movable portion 713BD in the X direction, and the fixing portions Y41 and Y42 are disposed on an inner side of the first movable portion 713BD.

The plurality of fixing portions GND51 are respectively connected to the first movable portions 713BA to 713BD via the first springs 714BA. In addition, the plurality of first springs 714BA also function as an electrical connection portion in addition to functioning as a mechanical connection portion.

In the present modification, by applying an optional voltage to the fixing portions X31, X32, X41, X42, Y31, Y32, Y41, and Y42, the first movable portions 713BA, 713BB, 713BC, and 713BD move independently, and the second movable portion 713BE moves in the X, Y, and ez directions. For example, when the same voltage is applied to the fixing portions X32 and X41, the first movable portions 713BA and 713BB equally move in the X direction (rightward), and the second movable portion 713BE moves in the +X direction (rightward). When the same voltage is applied to the fixing portions X32, X42, Y32, and Y42, the first movable portions 713BA, 713BB, 713BC, and 713BD equally move toward the center, and the second movable portion 713BE rotates in the eθz direction (clockwise).

The second movable portion 713BE is connected to the four first movable portions 713BA, 713BB, 713BC, and 713BD via the eight second springs 714BB. One end side of the second movable portion 713BE in the X direction is provided with two of the second springs 714BB, and the other end side thereof is also provided with two of the second springs 714BB. Further, one end side of the second movable portion 713BE in the Y direction is provided with two of the second springs 714BB, and the other end side thereof is also provided with two of the second springs 714BB. By appropriately designing the second springs 714BB, the first movable portions 713BA and 713BB can move only in the X direction, and the first movable portions 713BC and 713BD can move only in the Y direction. The second movable portion 713BE is fixed to the stage portion 711A via the adhesive layer 78A (see (b) of FIG. 2).

According to the present modification, the driving mechanism and the circuit for performing the translation in the X direction and the driving mechanism and the circuit for performing the translation in the Y direction are provided independently, and the rotation in the θz direction is also performed by controlling the translation in the X direction and the translation in the Y direction, so that the movements of the second movable portion 713BE in the X direction, the Y direction and/or the ez direction can be achieved.

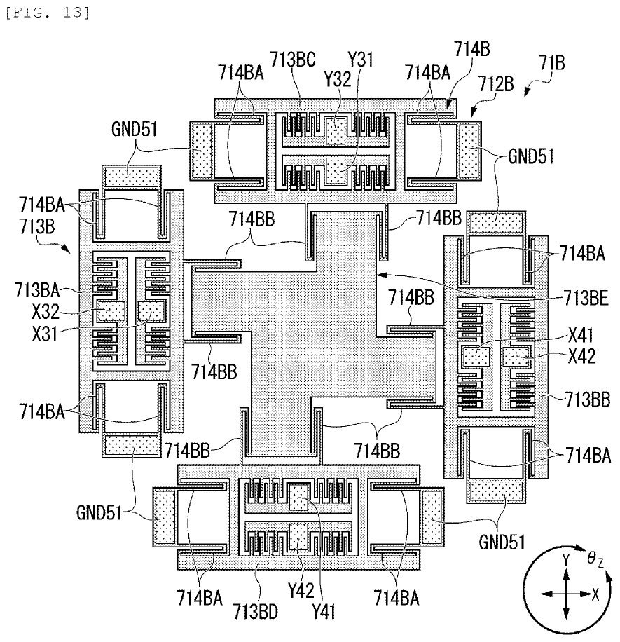

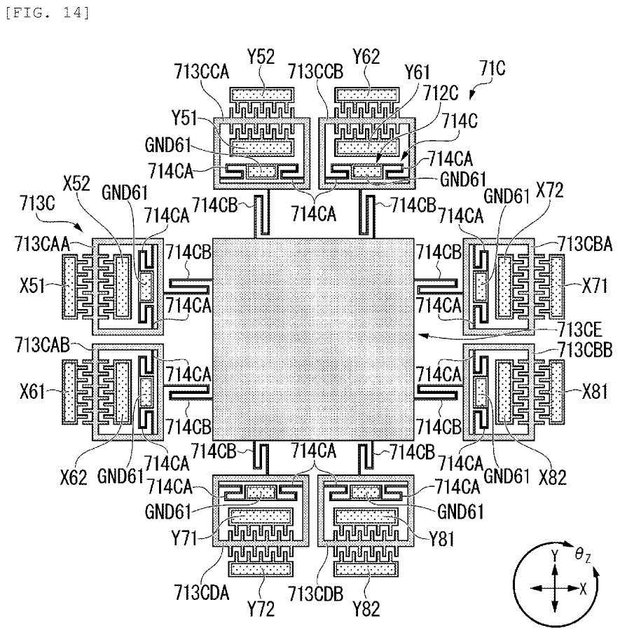

FIG. 14 is a bottom view showing another modification of the actuator 71A of FIG. 5.

As shown in FIG. 14, an actuator 71C includes a plurality of bases 712C fixed to the substrate 8 (see (b) of FIG. 2), a movable portion 713C mounted with the main part 731A of the flexible wiring body 73A and the semiconductor element 6, and a plurality of springs 714C connecting the bases 712C and the movable portion 713C. Similar to the actuator 71A, the actuator 71C is formed by, for example, MEMS.

The plurality of bases 712C include fixing portions X51, X52, GND61, X61, X62, and GND61 disposed on one end side of the actuator 71C with respect to the X direction, and fixing portions X71, X72, GND61, X81, X82, and GND61 disposed on the other end side of the actuator 71C with respect to the X direction. The fixing portions X51 and X52 are connected to the substrate 8 via an extraction electrode (not shown) (see (b) of FIG. 5). Since the other fixing portions have the same configuration, the description thereof will be omitted.

The two fixing portions X51 and X52 are formed with comb teeth of one side of a comb electrode, and comb teeth of the other side are formed in a first movable portion 713CAA to be described later. Similarly, the two fixing portions X61 and X62 are formed with comb teeth of one side of a comb electrode, and comb teeth of the other side are formed in a first movable portion 713CAB to be described later. The two fixing portions GND61 and GND61 are respectively connected to the first movable portion 713CAA and the first movable portion 713CAB to be described later via two first springs 714CA.

Further, the two fixing portions X71 and X72 are formed with comb teeth of one side of a comb electrode, and comb teeth of the other side are formed in a first movable portion 713CBA to be described later. Similarly, the two fixing portions X81 and X82 are formed with comb teeth of one side of a comb electrode, and comb teeth of the other side are formed in a first movable portion 713CBB to be described later. The two fixing portions GND61 and GND61 are respectively connected to the first movable portion 713CBA and the first movable portion 713CBB to be described later via two first springs 714CA.

The plurality of bases 712C include fixing portions Y51, Y52, GND61, Y61, Y62, and GND61 disposed on one end side of the actuator 71C with respect to the Y direction, and fixing portions Y71, Y72, GND61, Y81, Y82, and GND61 disposed on the other end side of the actuator 71C with respect to the Y direction.

The two fixing portions Y51 and Y52 are formed with comb teeth of one side of a comb electrode, and comb teeth of the other side are formed in a first movable portion 713CCA to be described later. Similarly, the two fixing portions Y61 and Y62 are formed with comb teeth of one side of a comb electrode, and comb teeth of the other side are formed in a first movable portion 713CCB to be described later. The two fixing portions GND61 and GND61 are respectively connected to the first movable portion 713CCA and the first movable portion 713CCB to be described later via two first springs 714CA.

Further, the two fixing portions Y71 and Y72 are formed with comb teeth of one side of a comb electrode, and comb teeth of the other side are formed in a first movable portion 713CDA to be described later. Similarly, the two fixing portions Y81 and Y82 are formed with comb teeth of one side of a comb electrode, and comb teeth of the other side are formed in a first movable portion 713CDB to be described later. The two fixing portions GND61 and GND61 are respectively connected to the first movable portion 713CDA and the first movable portion 713CDB to be described later via two first springs 714CA.

The movable portion 713C includes the eight first movable portions 713CAA, 713CAB, 713CBA, 713CBB, 713CCA, 713CCB, 713CDA and 713CDB disposed at four sides (XY directions) of a second movable portion to be described later, and a second movable portion 713CE disposed in a center of the eight first movable portions 713CAA to 713CDB, connected to the eight first movable portions 713CAA to 713CDB via a plurality of second springs 714CB, and having a substantially rectangular plate in the plan view.

The first movable portions 713CAA, 713CAB, 713CBA, 713CBB, 713CCA, 713CCB, 713CDA and 713CDB are, for example, frames having a substantially rectangular shape in the plan view. The fixing portion X51 is disposed on a side opposite to the second movable portion 713CE of the first movable portion 713CAA with respect to the X direction, and the fixing portions X52 and GND61 are disposed on an inner side of the first movable portion 713CAA. The fixing portion X61 is disposed on a side opposite to the second movable portion 713CE of the first movable portion 713CAB with respect to the X direction, and the fixing portions X52 and GND61 are disposed on an inner side of the first movable portion 713CAB.

Further, the fixing portion X71 is disposed on a side opposite to the second movable portion 713CE of the first movable portion 713CBA with respect to the X direction, and the fixing portions X72 and GND61 are disposed on an inner side of the first movable portion 713CBA. The fixing portion X81 is disposed on a side opposite to the second movable portion 713CE of the first movable portion 713CBB with respect to the X direction, and the fixing portions X82 and GND61 are disposed on an inner side of the first movable portion 713CBB.

Similarly, the fixing portion Y52 is disposed on a side opposite to the second movable portion 713CE of the first movable portion 713CCA with respect to the Y direction, and the fixing portions Y51 and GND61 are disposed on an inner side of the first movable portion 713CCA. In addition, the fixing portion X62 is disposed on a side opposite to the second movable portion 713CE of the first movable portion 713CCB with respect to the Y direction, and the fixing portions Y61 and GND61 are disposed on an inner side of the first movable portion 713CCB.

In addition, the fixing portion Y72 is disposed on a side opposite to the second movable portion 713CE of the first movable portion 713CDA with respect to the Y direction, and the fixing portions Y71 and GND61 are disposed on an inner side of the first movable portion 713CDA. In addition, the fixing portion Y82 is disposed on a side opposite to the second movable portion 713CE of the first movable portion 713CDB with respect to the Y direction, and the fixing portions Y81 and GND61 are disposed on an inner side of the first movable portion 713CDB.

The plurality of fixing portions GND61 are respectively connected to the first movable portions 713CAA to 713CDB via the first springs 714CA. In addition, the plurality of first springs 714CA also function as an electrical connection portion in addition to functioning as a mechanical connection portion.

In the present modification, when a voltage is applied to the fixing portions X52, X62, X71, and X81, the first movable portions 713CAA, 713CAB, 713CBA and 713CBB move in one side in the X direction (for example, +X direction), and when a voltage is applied to the fixing portions X51, X61, X72, and X82, the first movable portions 713CAA, 713CAB, 713CBA and 713CBB move in the other side in the X direction (for example, −X direction). On the other hand, when a voltage is applied to the fixing portions Y52, Y62, Y71, and Y81, the first movable portions 713BC, 713BD move in one side in the Y direction (for example, +Y direction), and when a voltage is applied to the fixing portions Y51, Y61, Y72, and Y82, the first movable portions 713BC, 713BD move in the other side in the Y direction (for example, −Y direction).

The second movable portion 713CE is connected to the eight first movable portions 713CAA, 713CAB, 713CBA, 713CBB, 713CCA, 713CCB, 713CDA, and 713CDB via the eight second springs 714CB. One end side of the second movable portion 713CE in the X direction is provided with two of the second springs 714CB, and the other end side thereof is also provided with two of the second springs 714CB. Further, one end side of the second movable portion 713BE in the Y direction is provided with two of the second springs 714CB, and the other end side thereof is also provided with two of the second springs 714CB. The second movable portion 713CE is fixed to the stage portion 711A via the adhesive layer 78A (see (b) of FIG. 2).

In the present modification, the second movable portion 713CE has the same potential as the fixing portion GND61. For example, when a voltage is applied to one of the fixing portions X52, X62, X71, X81 and the fixing portions X51, X61, X72, X82 and one of the fixing portions Y52, Y62, Y71, Y81 and the fixing portions Y51, Y61, Y72, Y82, the first movable portions 713CAA, 713CAB, 713CBA, and 713CBB move in one side of the X direction (for example, +X direction), and the first movable portions 713CCA, 713CCB, 713CDA, and 713CDB move in one side of the Y direction (for example, +Y direction). Further, along with the movements of the first movable portions 713CAA to 713CDB, the second movable portion 713CE moves in the X, Y, and θz directions. For example, when the same voltage is applied to the fixing portions X52, X62, X71, and X81, the first movable portions 713CAA, 713CAB, 713CBA, and 713CBB equally move in the +X direction (rightward), and the second movable portion 713CE moves in the +X direction (rightward). Further, when the same voltage is applied to the fixing portions X52, X61, X71, X82, Y52, Y61, Y71, and Y82, the first movable portions 713CAA and 713CBA move in the +X direction, the first movable portions 713CAB and 713CBB move in the −X direction, the first movable portions 713CCA and 713CDA move in the +Y direction (upward), the first movable portions 713CBB and 713CDB move in the −Y direction, and the second movable portion 713CE moves in the ez direction (clockwise).

By selectively applying a voltage to the predetermined fixing portions as described above, the first movable portions 713CAA to 713CDB translate in the X direction and/or the Y direction, and the second movable portion 713BE moves in the X, Y, and ez directions.

According to the present modification, the driving mechanism and the circuit for performing the translation in the X direction and the driving mechanism and the circuit for performing the translation in the Y direction are provided independently, and the rotation in the θz direction is also performed by controlling the translation in the X direction and the translation in the Y direction. Therefore, the movements of the second movable portion 713CE in the X direction, the Y direction and/or the ez direction can be achieved.

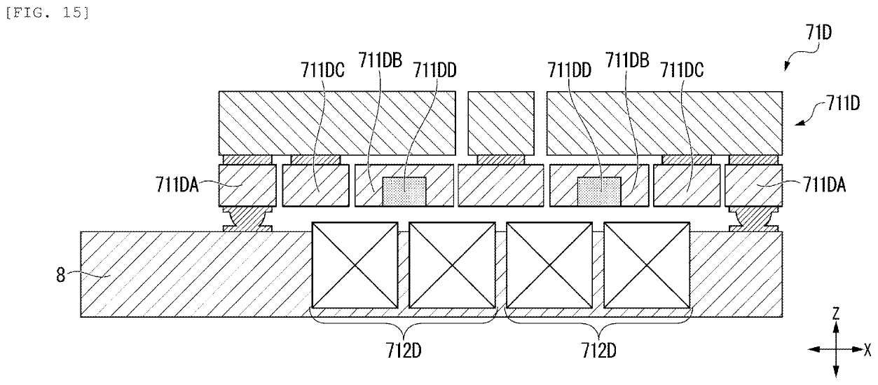

FIG. 15 is a cross-sectional view showing a modification of the actuator 71A in (b) of FIG. 2. The present modification differs from the actuator 71A in that the actuator is an electromagnetic actuator.

As shown in FIG. 15, an actuator 71D includes a MEMS 711D mounted to the substrate 8, and a plurality of coils 712D provided in the substrate 8 and electrically connected to an external circuit (not shown). The MEMS 711D includes bases 711DA supported by the substrate 8, movable portions 711DB fixed to the main part 731A of the flexible wiring body 73A and the semiconductor element 6, a plurality of springs 711DC connecting the bases 711DA and the movable portions 711DB, and a plurality of magnetic bodies 711DD mounted to the movable portions 711DB.

The plurality of coils 712D are disposed at positions immediately below the MEMS 711D and corresponding to the plurality of magnetic bodies 711DD, and are embedded in the substrate 8 such as a printed circuit board or a ceramic substrate. Configurations of the bases 711DA, the movable portions 711DB, and the plurality of springs 711DC of the MEMS 711D are basically the same as the configurations of the bases, the movable portions, and the plurality of springs of the actuator described above, and thus the description thereof will be omitted.

The magnetic bodies 711DD are formed using, for example, a magnetic powder such as neodymium magnet, and are embedded in the movable portions 711DB. The magnetic bodies 711DD can be obtained, for example, by forming a hole in a substrate such as an SOI by DRIE, and fixing a magnetic powder to the hole by film deposition in a state where the hole is filled with the magnetic powder. The magnetic powder is bonded together by the deposited film, and the deposited film is made of, for example, alumina (Al₂O₃), and is formed by atomic layer deposition (ALD). Alternatively, the magnetic powder is bonded together by a resin binder. Further, instead of embedding the magnetic powder, a magnetic body (for example, CoPt) may be formed in the hole by plating. Accordingly, a thickness of the magnetic bodies 711DD with respect to a thickness of the substrate such as an SOI can be increased, and the magnetic bodies 711DD having a high magnetic force can be formed in the movable portions 711DB.

The actuator 71D may include at least one displacement sensor that measures the displacement of at least one of the movable portions 711DB and the plurality of springs 711DC. For example, a displacement sensor and a circuit thereof can be formed in the MEMS 711D.

According to the present modification, the actuator 71D, which is an electromagnetic actuator, can be used to move the movable portions 711DB in the X direction, the Y direction, and/or the θz direction, and as in the case of the electrostatic actuator, it is possible to achieve the movement of the semiconductor element 6 with high accuracy.

The embodiments of the invention have been described above, but the invention is not limited to the above embodiments, and various modifications and changes can be made within the scope of the gist of the invention recited in the claims.

For example, in the present embodiment, the actuator 71A performs the translations in the X direction and the Y direction and the rotation about the axis in the Z direction (θz direction) among the XYZ directions orthogonal to one another, but the invention is not limited thereto, and the actuator 71A may perform at least one of the translations in the X direction, the Y direction, and the Z direction among the XYZ directions orthogonal to one another, the rotation about the axis in the X direction (θx direction), the rotation about the axis in the Y direction (ey direction), and the rotation about the axis in the Z direction (θz direction). When the flexible wiring body having the same configuration as above is used for such an actuator, the plurality of arm parts can also follow at least one of the translations in three directions orthogonal to one another and the rotations around the axes in the three directions, the positioning performance of the semiconductor element mounted on the main part can be improved, and both the high-frequency signal for high-speed communication and the large current for driving the imaging element can flow stably.

### REFERENCE SIGN LIST

1 imaging device

2 lens

3 AF unit

4 glass member

5 cover member

6 semiconductor element

6a lower surface

6b side surface

7 driving system

8 substrate

71A actuator

71B actuator

71C actuator

71D actuator

72a frame

72a upper surface

73A flexible wiring body

73B flexible wiring body

73C flexible wiring body

74A adhesive layer

75A adhesive layer

76A adhesive layer

77 wire portion

78A adhesive layer

79A extraction electrode

80A adhesive layer

81A accommodation portion

82A adhesive layer

83A adhesive layer

84A joint portion

711a upper surface

711A stage portion

711b side surface

711DA base

711DB movable portion

711DC spring

711DD magnetic body

712A base

712B base

712C base

712D coil

713A movable portion

713AA first movable portion

713AB first movable portion

713AC first movable portion

713AD first movable portion

713AE second movable portion

713AF third movable portion

713B movable portion

713BA first movable portion

713BB first movable portion

713BC first movable portion

713BD first movable portion

713BE second movable portion

713C movable portion

713CAA first movable portion

713CAB first movable portion

713CBA first movable portion

713CBB first movable portion

713CCA first movable portion

713CCB first movable portion

713CDA first movable portion

713CDB first movable portion

713CE second movable portion

714A spring

714AA first spring

714AB second spring

714AC third spring

714B spring

714BA first spring

714BB second spring

714C spring

714CA first spring

714CB second spring

715AA insulating portion

715AB insulating portion

715AC insulating portion

715AD insulating portion

715AE insulating portion

715AF insulating portion

715AG insulating portion

715AH insulating portion

716AA insulating portion

716AB insulating portion

716ABa first layer

716ABb second layer

716AC insulating portion

716AD insulating portion

716AE insulating portion

716AF insulating portion

731a main surface

731A main part

731b main surface

731B main part

731C main part

731c main surface

732a main surface

732A arm part

732Aa first portion

732Ab second portion

732Ac third portion

732Ad fourth portion

732b main surface

732B arm part

732Ba first portion

732Bb second portion

732Bc third portion

732Bd fourth portion

732Bda extension portion

732Bdb extension portion

732Be fifth portion

732c main surface

732C arm part

732Ca first portion

732Cb second portion

732Cc third portion

732Cd fourth portion

732Cda extension portion

732Cdb extension portion

732d main surface

732e main surface

732f main surface

733A resin layer

733B resin layer

733C resin layer

734A conductive layer

734Aa one end portion

734Ab the other end portion

734B conductive layer

734Ba one end portion

734Bb the other end portion

734C conductive layer

734Ca one end portion

734Cb the other end portion

X11, X12, GND14, GND15, θ12 fixing portion

X21, X22, θ22, GND23, GND25 fixing portion

Y11, Y12, GND31, GND35, θ31 fixing portion

Y21, Y22, θ41, GND42, GND45 fixing portion

X31, X32, GND51 fixing portion

X41, X42, GND51 fixing portion

Y31, Y32, GND51 fixing portion

Y41, Y42, GND51 fixing portion

X51, X52, GND61, X61, X62 fixing portion

X71, X72, GND61, X81, X82 fixing portion

Y51, Y52, GND61, Y61, Y62 fixing portion

Y71, Y72, GND61, Y81, Y82 fixing portion

θ51, θ52, GND55, θ61, θ62, GND65 moving portion

1. A flexible wiring body configured to connect a semiconductor element and a frame positioned outer than the semiconductor element, the semiconductor element being configured to move along with an actuator configured to perform at least one among translations in three directions orthogonal to one another and rotations about axes in the three directions, the flexible wiring body comprising:
a main part mounted with the semiconductor element and electrically connected to the semiconductor element; and
a plurality of arm parts extending from the main part toward the frame and configured to be bent three-dimensionally.

2. The flexible wiring body according to claim 1, wherein
the arm parts are bent to have a main surface that intersects with a main surface of the main part, and are further bent by folding back, and
the deformation of the arm parts provides freedom in rotations around axes in a horizontal direction and a vertical direction of the semiconductor element, and a direction perpendicular to a main surface of the semiconductor element.

3. The flexible wiring body according to claim 1 or 2, wherein
the number of the plurality of arm parts is four or more.

4. The flexible wiring body according to any one of claims 1 to 3, wherein
in a plan view of the main part, the plurality of arm parts are disposed symmetrically with respect to the main part, and
the plurality of arm parts are bent by folding back to maintain a state where forces due to elastic deformation are balanced.

5. The flexible wiring body according to any one of claims 1 to 4, wherein
the arm parts include:
a first portion having a main surface substantially perpendicular to a main surface of the main part;
a second portion provided at one end of the first portion and bent by folding back;
a third portion disposed facing the first portion; and
a fourth portion provided at one end of the third portion and having a main surface substantially parallel to the main surface of the main part, and
the first portion, the second portion and the third portion are disposed substantially perpendicular to the main surface of the main part.

6. The flexible wiring body according to any one of claims 1 to 5, wherein
the arm parts include a resin layer and a plurality of linear conductive wires formed in parallel on the resin layer and insulated from each other.

7. The flexible wiring body according to claim 6, wherein
the plurality of arm parts have a total of 20 or more of the conductive wires.

8. A driving system, comprising:
an actuator configured to perform at least one among translations in three directions orthogonal to one another and rotations about axes in the three directions; and
the flexible wiring body according to any one of claims 1 to 7, wherein
the actuator includes:
a base fixed to a substrate;
a movable portion mounted with the main part of the flexible wiring body and the semiconductor element; and
a plurality of springs connecting the base and the movable portion.

9. The driving system according to claim 8, further comprising:
at least one displacement sensor configured to measure displacement of at least one of the movable portion and the plurality of springs.

10. The driving system according to claim 8, wherein the actuator is formed by MEMS.

11. The driving system according to any one of claims 8 to 10, wherein
the actuator is an electrostatic actuator.

12. The driving system according to any one of claims 8 to 10, wherein
the actuator is an electromagnetic actuator.

13. The driving system according to claim 12, wherein
the actuator is provided with a MEMS mounted on the substrate, and at least one coil provided within the substrate and electrically connected to an external circuit, and
the MEMS includes a base supported by the substrate, a movable portion fixed to the main part of the flexible wiring body and the semiconductor element, a plurality of springs connecting the base and the movable portion, and at least one magnetic body mounted to the movable portion.

14. The driving system according to claim 13, wherein
the magnetic body is formed using a magnetic powder or a plated material, and is embedded in the movable portion.

15. The driving system according to claim 14, wherein
the magnetic powder is bonded together by means of a deposited film or a resin binder.

16. The driving system according to any one of claims 8 to 13, wherein
the semiconductor element is an image sensor.

17. An imaging device, comprising:
the driving system according to claim 16, wherein
the driving system is configured to perform one or both of optical image stabilization and focus adjustment by driving the image sensor.
